(19) United States
(12) Patent Application Publication
(10) Pub. No.: US 2026/0223329 A1
(43) Pub. Date: Jul. 30, 2026

(54) IMMERSION COOLING ASSEMBLY FOR CONTROLLING THE TEMPERATURE OF ELECTRONIC DEVICES IN A VEHICLE

(71) Applicant: Toyota Motor Engineering & Manufacturing North America, Inc., Plano, TX (US)

(72) Inventors: Shailesh N. Joshi, Ann Arbor, MI (US); Ercan M. Dede, Ann Arbor, MI (US)

(73) Assignee: Toyota Motor Engineering & Manufacturing North America, Inc., Plano, TX (US)

(21) Appl. No.: 19/041,379

(22) Filed: Jan. 30, 2025

(51) Int. Cl. H05K 7/20

(52) U.S. Cl. CPC H05K 7/20327; H05K 7/203; H05K 7/20318; H05K 7/20881

(57) ABSTRACT

An immersion cooling assembly for controlling the temperature of electronic devices in a vehicle includes a tank and a liquid coolant disposed in the tank. The immersion cooling assembly includes a first electronic device disposed in the tank and at least partially submerged in the liquid coolant. The immersion cooling assembly includes a second electronic device disposed in the tank and at least partially submerged in the liquid coolant, the second electronic device spaced from first electronic device along a lateral direction. The immersion cooling assembly includes a perforated baffle disposed in the tank between the first electronic device and the second electronic device along the lateral direction and at least partially submerged in the liquid coolant.

### TECHNICAL FIELD

The present specification generally relates to an apparatus for controlling the temperature of electronic devices in a mobile environment and, more specifically, to an apparatus for controlling the temperature of electronic devices that reduces sloshing of liquid coolant in the mobile environment.

### BACKGROUND

Immersion cooling systems for electronic devices are typically used in a stationary environment, e.g., supported by a floor of a building, a server rack, and/or the like. Use of immersion cooling systems for electronic devices in a mobile environment, e.g., supported by a vehicle that is in motion, may cause sloshing of liquid coolant and decrease cooling performance.

Accordingly, a need exists for an apparatus for controlling the temperature of electronic devices that reduces sloshing of liquid coolant in a mobile environment.

### SUMMARY

In one embodiment, an immersion cooling assembly for controlling the temperature of electronic devices in a mobile environment includes a tank and a liquid coolant disposed in the tank. The immersion cooling assembly includes a first electronic device disposed in the tank and at least partially submerged in the liquid coolant. The immersion cooling assembly includes a second electronic device disposed in the tank and at least partially submerged in the liquid coolant, the second electronic device spaced from first electronic device along a lateral direction. The immersion cooling assembly includes a perforated baffle disposed in the tank between the first electronic device and the second electronic device along the lateral direction and at least partially submerged in the liquid coolant. The perforated baffle is configured to break up coolant gas-phase bubbles formed in the liquid coolant caused from a heat generated by the first electronic device or the second electronic device and/or to reduce sloshing of the liquid coolant.

In another embodiment, an immersion cooling assembly for controlling the temperature of electronic devices in a mobile environment includes a tank and a liquid coolant disposed in the tank. The immersion cooling assembly includes an electronic device disposed in the tank and submerged in the liquid coolant. The immersion cooling assembly includes a perforated baffle disposed in the tank directly above the electronic device and at least partially submerged in the liquid coolant. The perforated baffle is configured to break up coolant gas-phase bubbles formed in the liquid coolant caused from a heat generated by the electronic device and/or to reduce sloshing of the liquid coolant.

These and additional features provided by the embodiments described herein will be more fully understood in view of the following detailed description, in conjunction with the drawings. While specific embodiments are identified, it will be understood that elements from one described aspect may be combined with those from a separately identified aspect.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view of a vehicle having an example immersion cooling assembly according to one or more embodiments shown and described herein;

FIG. 2 schematically depicts a cross-section of the example immersion cooling assembly of FIG. 1 according to one or more embodiments shown and described herein;

FIG. 3 schematically depicts a cross-section of another example immersion cooling assembly according to one or more embodiments shown and described herein; and

FIG. 4 schematically depicts a lattice structure for use in the example immersion cooling assemblies.

### DETAILED DESCRIPTION

Embodiments described herein are directed to an immersion cooling assembly for controlling the temperature of electronic devices in a mobile environment, such as in a vehicle. The immersion cooling assembly generally includes a tank, a liquid coolant disposed in the tank, one or more electronic devices disposed in the tank and at least partially submerged in the liquid coolant, and one or more perforated baffles disposed in the tank and at least partially submerged in the liquid coolant. The perforated baffles may control kinematics of the liquid coolant, e.g., to reduce or eliminate sloshing of the liquid coolant, and thereby increase heat transfer efficiency in removing heat from the electronic devices. Various embodiments of the immersion cooling assembly for controlling the temperature of electronic devices in a vehicle are described in more detail herein.

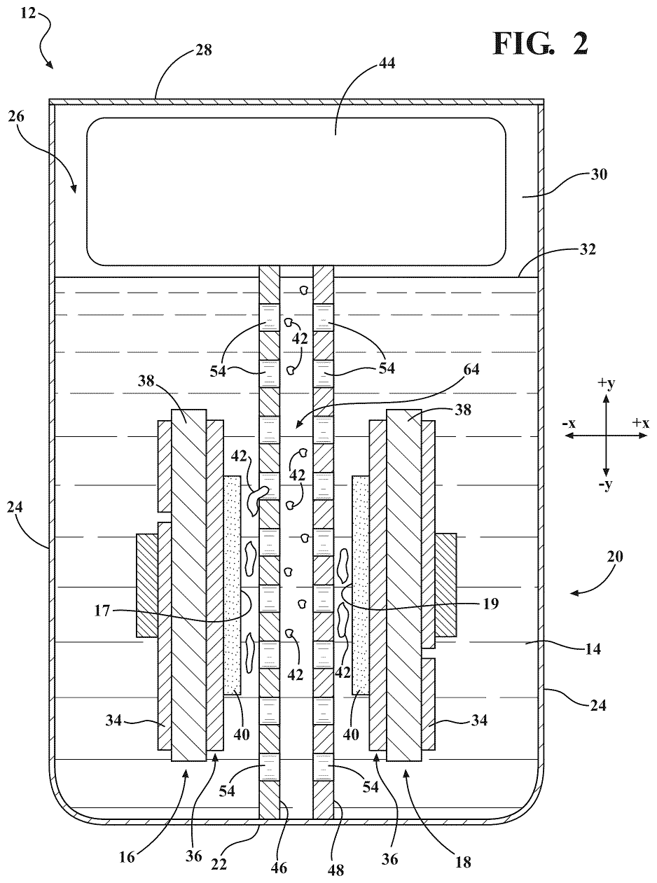

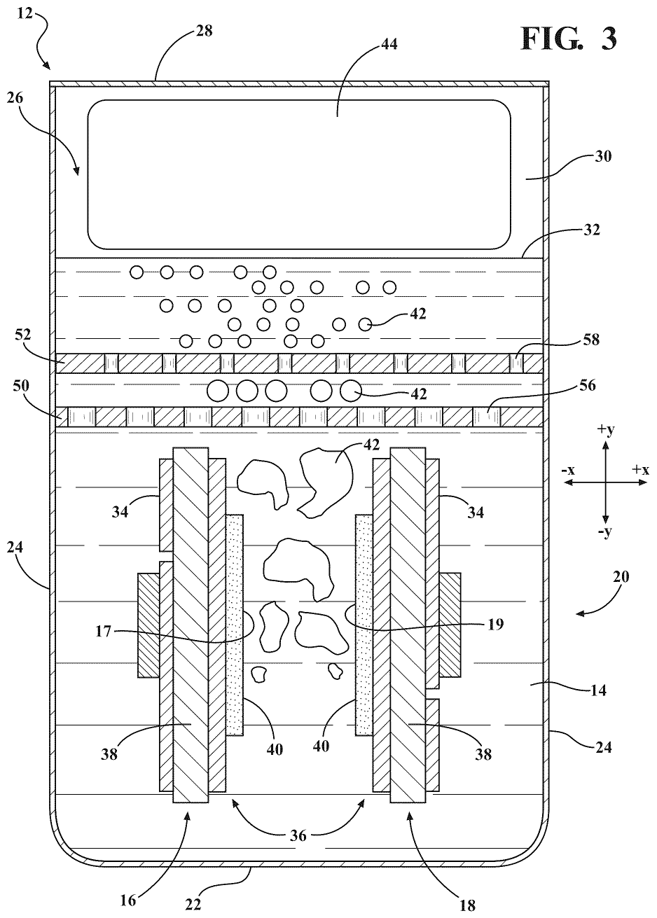

Directional terms as used herein-for example up, down, right, left, front, back, top, bottom—are made only with reference to the figures as drawn and are not intended to imply absolute orientation. The terms “vertical,” “above,” “below,” and/or the like, refer to the upward-downward direction of the example immersion cooling assembly (i.e., in the +/−Y-direction depicted in FIGS. 2 and 3. That is, the terms “above” is defined as generally being towards the positive Y direction of the coordinate axes shown in the drawings. “Below” is defined as generally being towards the negative Y direction of the coordinate axes shown in the drawings. The terms “lateral” and the like refers to a direction that is generally perpendicular to vertical (i.e., in the +/−Y direction depicted in FIGS. 2 and 3), e.g., in a generally forward-rearward direction and/or a generally left/right direction.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

As used herein, the singular forms “a,” “an” and “the” include plural referents unless the context clearly dictates otherwise. Thus, for example, reference to “a” component includes aspects having two or more such components, unless the context clearly indicates otherwise.

Whenever possible, the same reference numerals will be used throughout the drawings to refer to the same or like parts.

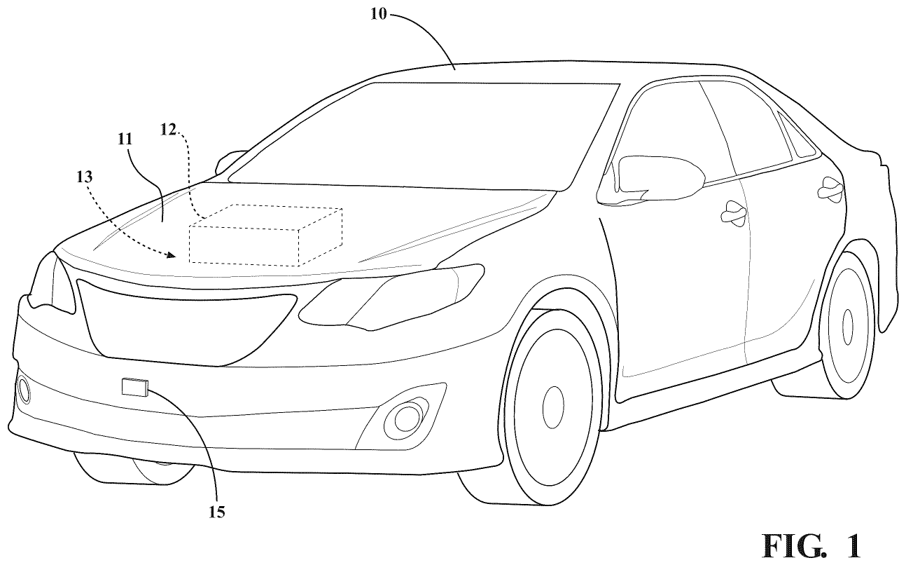

Referring now to FIG. 1, a vehicle 10 having an example immersion cooling assembly 12 is schematically depicted. The immersion cooling assembly 12 is configured to utilize a liquid coolant 14 as a heat transfer medium for controlling the temperature of one or more electronic devices 16, 18 (schematically shown in FIGS. 2 and 3).

The vehicle 10 may be, for example, and without limitation, a car, van, sport utility vehicle, bus, boat, airplane, and/or any other type of vehicle configured for movement. The vehicle 10 may operate in an autonomous mode, i.e., with limited human input or without human input. The example immersion cooling assembly 12 may be supported by, e.g., fixed to, the vehicle 10, e.g., under a hood 11 in a front vehicle compartment 13 (as shown), at a rear vehicle compartment (not shown), by a roof of the vehicle, e.g., within a housing supported by the roof and including sensors to autonomously operate the vehicle 10 such as cameras, LIDAR sensors, and/or the like (not shown), or any other suitable structure of the vehicle 10. The example immersion cooling assembly 12 is schematically represented and is not shown to scale, e.g., relative to the shown size of the vehicle 10.

With reference to FIGS. 2 and 3, the one or more electronic devices 16, 18 may facilitate operation of various components and/or systems of the vehicle 10 that rely on the each of the one or more electronic devices 16, 18 for information processing, analysis, generating electronic commands, and/or the like. For example, and without limitation. operation of the vehicle 10 in the autonomous mode. For example, and without limitation, each of the one or more electronic devices 16, 18 may be configured to analyze image data, (e.g., captured by a camera or a LIDAR device 15), to identify objects in a vicinity of the vehicle 10 and to navigate the vehicle 10 to avoid contact with the identified objects.

The liquid coolant 14 may include, for example, and without limitation, water, ethylene glycol (EG), propylene glycol (PG), and/or the like. The liquid coolant 14 may be a dielectric liquid that provides electrical isolation to the one or more electronic devices 16, 18. For example, the liquid coolant 14 may include mineral oil, n-Hexane, n-Heptane, castor oil natural ester, refined and dried castor oil, Hatcol 5005 synthetic ester, silicone oil, fluorinert FC-72, Novec 649, Novec 7100, polychlorinated biphenyls, purified water, liquid nitrogen, liquid helium, liquid argon, or other suitable dielectric liquid.

The example immersion cooling assembly 12 may be a single-phase or a two-phase cooler. As a single-phase cooler, the liquid coolant 14 maintains a single-phase state, i.e., liquid. To put it another way, when the example immersion cooling assembly 12 is a single-phase cooler, the liquid coolant 14 maintains in the liquid-phase state during operation and merely changes temperature when removing heat from the one or more electronic devices 16, 18. As a two-phase cooler the liquid coolant 14 changes-phase state, i.e., from liquid to gas and vice-versa. To put it another way, when the example immersion cooling assembly 12 is a two-phase cooler, the liquid coolant 14 may change from the liquid state to a gas state when removing heat from one or more electronic devices 16, 18. The liquid coolant 14 may change stage to gas when heated to a boiling point of the liquid coolant 14. For example, water as the liquid coolant 14 and at 1 atmosphere (atm) of pressure would change phase from liquid to gas when heated by the one or more electronic devices 16, 18 to 100 degrees Celsius.

With continued reference to FIGS. 2 and 3, the example immersion cooling assembly 12 includes a tank 20 for containing the liquid coolant 14 and supporting components, such as the one or more electronic devices 16, 18, of the example immersion cooling assembly 12. The tank 20 may include, for example and without limitation, a base 22 and sidewalls 24 joined to the base 22 and extending from the base 22. The sidewalls 24 may circumferentially surround the base 22. For example, and without limitation, a pair of sidewalls 24 that are spaced from each other along the lateral direction (i.e., in the +/−X direction) may extend upward from opposite ends of the base 22 along the vertical direction (i.e., in the +/−Y direction). Another pair of sidewalls 24 (not shown) may be spaced from each other along a direction that is perpendicular to both the lateral direction (i.e., in the +/−X direction) and the vertical direction (i.e., in the +/−Y direction), may extend upward along the vertical direction (i.e., in the +/−Y direction) from opposite ends of the base 22, and may extend along the lateral direction (i.e., in the +/−X direction) from one of the sidewalls 24 spaced from each other along the lateral direction (i.e., in the +/−X direction) to the other of the sidewalls 24 spaced from each other along the lateral direction (i.e., in the +/−X direction).

The base 22 and the sidewalls 24 may define a chamber 26. The base 22 may define a bottom of the chamber 26 and the sidewalls 24 may define sides of the chamber 26. The tank 20 may include a top wall 28 connected to the sidewalls walls opposite the base 22. The top wall 28 may further define the chamber 26, e.g., enclosing or defining a top of the chamber 26. One or more components of the tank 20, e.g., the base 22, sidewalls 24, and/or the top wall 28, may be monolithic. For the purposes of this disclosure, “monolithic” means a single-piece unit, i.e., a continuous piece of material without any fasteners, joints, welding, adhesives, and/or the like, fixing multiple pieces to each other. For example, the tank 20 may be formed in a common injection mold operation, 3-D printed in a same operation, a stamping operation, etc. Alternately, components of the tank 20, e.g., the base 22, sidewalls 24, and/or the top wall 28, may be individually formed and the secured to each other, e.g., via fasteners, such as, without limitation, weld, screw, rivet, nut and bolt, adhesive, epoxy, and/or other suitable structure and/or process. The tank 20 may be formed from metal, plastic, fiberglass, or any other suitable material.

The liquid coolant 14 is disposed in and retained by the chamber 26 of the tank 20. For example, and without limitation, the chamber 26 defined by the tank 20 may be at least partially filled with the liquid coolant 14. The liquid coolant 14 in the chamber 26 may be spaced from the top wall 28, e.g., to provide a volume 30 within the chamber 26 that is generally free of liquid coolant 14. In other words, the tank 20 may include fluid other than liquid coolant 14 e.g., a gas disposed therein along with the liquid coolant 14. The fluid and the liquid coolant 14 may be generally maintained separate from each other, e.g., due to gravitationally forces.

The one or more electronic devices 16, 18 are disposed in the chamber 26 of the tank 20. For example, and without limitation, the example immersion cooling assembly 12 may include a first electronic device 16 and a second electronic device 18 positioned within the chamber 26 of the tank 20. It is to be understood and appreciated that a lesser number, e.g., just one, or a greater number, e.g., three or more, electronic devices 16, 18 may be positioned within the chamber 26 of the tank 20.

The one or more electronic devices 16, 18 may be configured to process information and/or command vehicle components, for example and without limitation, to facilitate autonomous operation of one or more vehicles systems, such as a braking system, a steering system, a propulsion system, and/or the like. Each one or more electronic device 16, 18 may include, for example, circuit board assembly 34 attached to a direct bonded copper (DBC) substrate 36. For example, in some embodiments, the circuit board assembly 34 may be a printed circuit board (PCB). In other embodiments, the circuit board assembly 34 may be flexible, rigid, high-density interconnect, and/or the like. Further, in some embodiments, the circuit board assembly 34 may be a single layer. In other embodiments, the circuit board assembly 34 may be multi-layered.

The circuit board assembly 34 for each of the one or more electronic devices 16, 18 may be powered devices that include one or more insulated-gate bipolar transistors (IGBTs), one or more metal-oxide-semiconductor field-effect transistors (MOSFETs), Insulated-gate bipolar transistors (IGBTs), and/or the like. For example, and without limitation, the circuit board assembly 34 may include semiconductors, control/drive/protection electronic circuitry, power devices, and/or passive components, embedded therein. The circuit board assembly 34 for each of the one or more electronic devices 16, 18 may include a plurality of dielectric layers and a plurality of power layers. The power layers may include a dielectric material and a conductive material. The dielectric layers may include the dielectric material and conductive vias that provide electrical communication or pathways between adjacent power layers. Stated differently, the power layers may include conductive (e.g., copper) patterns and the dielectric layers may include conductive (e.g., copper) pathways that connect the conductive patterns such that the circuit board assembly 34 for each of the one or more electronic devices 16, 18 function and/or operate as desired.

The DBC substrate 36 may include a ceramic base 38 and a copper layer 40 opposite the circuit board assembly 34. The ceramic base 38 may be configured to electrically insulate the circuit board assembly 34 from the copper layer 40. Material other than ceramic may be used for the DBC substrate 36. For example, and without limitation, the base 38 may be aluminum, or other material having generally high thermally conductivity. A dielectric layer may be included between the base 38 and the copper layer 40, e.g., when the base 38 is an electrically conductive material, to insulate the base 38 and the copper layer 40, using known techniques to those skilled in the art.

During operation of the electronic device 16, 18, the circuit board assembly 34 may generate heat. The generated heat may be drawn away from the circuit board assembly 34 by the DBC substrate 36, e.g., maintaining the temperature of the circuit board assembly 34 below a maximum operating temperature of the circuit board assembly 34. For example, the maximum operating temperature may be generally in a range of about 90 to about 110 degrees Celsius. The heat may flow through the base 38 and to the copper layer 40 of the DBC substrate 36. At the copper layer 40, the heat may be absorbed by the liquid coolant 14 retained in the chamber 26 of the tank 20, e.g., causing the coolant 14 to undergo a phase change to gas and generate bubbles 42.

The one or more electronic devices 16, 18, (e.g., the first electronic device 16 and the second electronic device 18) may be spaced from each other the along the lateral direction (i.e., in the +/−X direction). Each of the one or more electronic devices 16, 18 in the chamber 26 of the tank 20 may be elongated along the vertical direction (i.e., in the +/−Y direction). That is, a height of each of the one or more electronic devices 16, 18 along the vertical direction (i.e., in the +/−Y direction) may be longer that a width of each of the one or more electronic devices 16, 18 along the lateral direction (i.e., in the +/−X direction). The first electronic device 16 and the second electronic device 18 may be oriented such that a phase-transition surface 17 of first electronic device 16 and a phase-transition surface 19 of the second electronic device 18 face each other. For example, and without limitation, the copper layer 40 of the first electronic device 16 may face the copper layer 40 of the second electronic device 18. In other words, the copper layers 40 of the first and second electronic devices 16, 18 may be between the circuit board assemblies 34 and the ceramic bases 38 of the first and second electronic devices 16, 18, respectively.

As schematically depicted in FIGS. 2 and 3, the one or more electronic devices 16, 18 may be fully submerged in the liquid coolant 14, i.e., fully encapsulated by the liquid coolant 14. That is, a top surface 32 of the liquid coolant 14 in the chamber 26 of the tank 20 may be above top-most distal ends of the one or more electronic devices 16, 18 along the vertical direction (i.e., in the +/−Y direction). The one or more electronic devices 16, 18 may be partially submerged in the liquid coolant 14 in the tank 20 (not shown). That is, the one or more electronic devices 16, 18 may extend from within the liquid coolant 14 in the tank 20 to above the top surface 32 of the liquid coolant 14 in the tank 20 along the vertical direction (i.e., in the +/−Y direction).

The example immersion cooling assembly 12 may include a condenser 44. The condenser 44 may disposed in chamber 26 of the tank 20 above the liquid coolant 14 in the vertical direction (i.e., in the +/−Y direction). For example, the condenser 44 may be disposed in the volume 30 above the top surface 32 of the liquid coolant 14, e.g., in the chamber 26 proximate the top wall 28. The condenser 44 may be included in the example immersion cooling assembly 12 to remove heat from coolant in a gas state in the volume 30 such that the gas undergoes a phase transition to the liquid state. The condenser 44 relies on the efficient heat transfer that occurs during phase changes, in this case during the condensation of coolant fluid in the gas-phase to the liquid-phase. The gas-phase coolant contacts an outer surface of the condenser 44 at a temperature above that of a secondary fluid that is circulated through the condenser 44. As the gas-phase coolant cools, it reaches the saturation temperature, condenses into liquid along the outer surface of the condenser 44, and releases large quantities of latent heat. As this process occurs, the quantity of gas-phase coolant retained in the chamber 26 of the tank 20 decreases and the quantity of liquid coolant 14 increases.

One or more perforated baffles 46, 48, 50, 52 are provided in the tank 20 to reduce sloshing and/or other agitation of the liquid coolant 14. For example, and as further discussed below, the one more perforated baffles 46, 48 may reduce movement of the liquid coolant 14 within the tank 20 in the lateral direction (i.e., in the +/−X direction) and/or the vertical direction (i.e., in the +/−Y direction), and may break up and generally disperse gas bubbles 42 in the liquid coolant 14, e.g., produced when the liquid coolant 14 undergoes a phase change from the liquid state to a gas state in response to sufficient heat being transferred to the liquid coolant 14 from the one or more electronic devices 16, 18. The one or more perforated baffles 46, 48, 50, 52 are positioned between the base 22 and the condenser 44 along the vertical direction (i.e., in the +/−Y direction). Each of the perforated baffles 46, 48, 50, 52 may be fully or partially submerged in the liquid coolant 14, as further discussed below. The one or more perforated baffles 46, 48, 50, 52 may extend completely across the chamber 26, e.g., from one sidewall 24 to an opposite sidewall 24, and as further discussed below. The one or more perforated baffles 46, 48, 50, 52 may be supported by the tank 20, for example and without limitation, fixed to the base 22 and/or the sidewalls 24.

Each perforated baffle 46, 48, 50, 52 includes one or more openings 54, 56, 58 that permit fluid, such as the liquid coolant 14 and/or bubbles 42 therein, to flow from one side of the perforated baffle 46, 48, 50, 52 to an opposite side of the perforated baffle 46, 48, 50, 52. The openings 54, 56, 58 may have a same size at each other, and/or may vary in size. The openings 54, 56, 58 may be distributed uniformly or not uniformly. The openings 54, 56, 58 may be circular or any shape, including irregular shapes.

As one not-limiting example, the openings 54, 56, 58 may be provided by through holes that extend through the perforated baffles 46, 48, 50, 52. The openings 54, 56, 58 may extend along the lateral direction (i.e., in the +/−X direction), the vertical direction (i.e., in the +/−Y direction), and/or transverse to the lateral direction (i.e., in the +/−X direction) and the vertical direction (i.e., in the +/−Y direction).

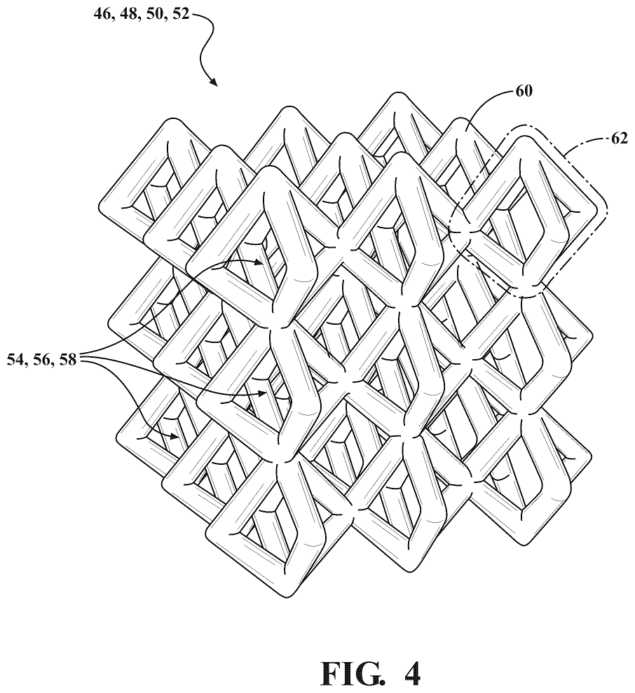

As another non-limiting example, the perforated baffles 46, 48, 50, 52 may include a lattice structure 60, e.g., as shown in FIG. 4. The lattice structure 60 includes interconnected porous unit cells 62 that are arranged in a periodic and regular fashion. The interconnected porous unit cells 62 are open celled to provide the openings 54, 56, 58, i.e., such that fluid can flow into, and through each unit cell 62. The unit cells 62 may be for example and without limitation, hexagonal, octagonal, or any other suitable shape. The lattice structure 60 may be provided, for example, by additive manufacturing, or any other suitable process.

The examples shown for the perforated baffles 46, 48, 50, 52 having openings 54, 56, 58 are non-limiting, and other baffles such as screens, honeycomb cores, and simple perforated plates (i.e., plates with different size holes) are conceivable using either additive or subtractive manufacturing processes.

As used herein, the terms “additively manufactured” or “additive manufacturing techniques or processes” refer generally to manufacturing processes wherein successive layers of material(s) are provided on each other to “build-up,” layer-by-layer, a three-dimensional component. The successive layers generally fuse together to form a monolithic component which may have a variety of integral sub-components. Although additive manufacturing technology is described herein as enabling fabrication of complex objects by building objects point-by-point, layer-by-layer, typically in a vertical direction, other methods of fabrication are possible and within the scope of the present subject matter. For example, although the discussion herein refers to the addition of material to form successive layers, one skilled in the art will appreciate that the methods and structures disclosed herein may be practiced with any additive manufacturing technique or manufacturing technology. For example, embodiments of the present invention may use layer-additive processes, layer-subtractive processes, or hybrid processes.

Suitable additive manufacturing techniques in accordance with the present disclosure may include, for example and without limitation, Fused Deposition Modeling (FDM), Selective Laser Sintering (SLS), 3D printing such as by inkjets and laserjets, Sterolithography (SLA), Direct Selective Laser Sintering (DSLS), Electron Beam Sintering (EBS), Electron Beam Melting (EBM), Laser Engineered Net Shaping (LENS), Laser Net Shape Manufacturing (LNSM), Direct Metal Deposition (DMD), Digital Light Processing (DLP), Direct Selective Laser Melting (DSLM), Selective Laser Melting (SLM), Direct Metal Laser Melting (DMLM), and other known processes.

The additive manufacturing processes described herein may be used for forming components using any suitable material. For example, the material may be plastic, metal, concrete, ceramic, polymer, epoxy, photopolymer resin, or any other suitable material that may be in solid, liquid, powder, sheet material, wire, or any other suitable form. More specifically, according to exemplary embodiments of the present subject matter, the additively manufactured components described herein may be formed in part, in whole, or in some combination of materials including but not limited to pure metals, nickel alloys, chrome alloys, titanium, titanium alloys, magnesium, magnesium alloys, aluminum, aluminum alloys, and nickel or cobalt base superalloys (e.g., those available under the name Inconel® available from Special Metals Corporation). These materials are examples of materials suitable for use in the additive manufacturing processes described herein, and may be generally referred to as “additive materials.”

In addition, one skilled in the art will appreciate that a variety of materials and methods for bonding those materials may be used and are contemplated as within the scope of the present disclosure. As used herein, references to “fusing” may refer to any suitable process for creating a bonded layer of any of the above materials. For example, if an object is made from polymer, fusing may refer to creating a thermoset bond between polymer materials. If the object is epoxy, the bond may be formed by a crosslinking process. If the material is ceramic, the bond may be formed by a sintering process. If the material is powdered metal, the bond may be formed by a melting or sintering process. One skilled in the art will appreciate that other methods of fusing materials to make a component by additive manufacturing are possible, and the presently disclosed subject matter may be practiced with those methods.

In addition, the additive manufacturing process disclosed herein allows a single component to be formed from multiple materials. Thus, the components described herein may be formed from any suitable mixtures of the above materials. For example, a component may include multiple layers, segments, or parts that are formed using different materials, processes, and/or on different additive manufacturing machines. In this manner, components may be constructed which have different materials and material properties for meeting the demands of any particular application. In addition, although the components described herein are constructed entirely by additive manufacturing processes, it should be appreciated that in alternate embodiments, all or a portion of these components may be formed via casting, machining, and/or any other suitable manufacturing process. Indeed, any suitable combination of materials and manufacturing methods may be used to form these components.

An exemplary additive manufacturing process will now be described. Additive manufacturing processes fabricate components using three-dimensional (3D) information, for example a three-dimensional computer model, of the component. Accordingly, a three-dimensional design model of the component may be defined prior to manufacturing. In this regard, a model or prototype of the component may be scanned to determine the three-dimensional information of the component. As another example, a model of the component may be constructed using a suitable computer aided design (CAD) program to define the three-dimensional design model of the component.

The design model may include 3D numeric coordinates of the entire configuration of the component including both external and internal surfaces of the component. For example, the design model may define the body, the surface, and/or internal passageways such as openings 54, 56, 58, support structures, and the like. In one exemplary embodiment, the three-dimensional design model is converted into a plurality of slices or segments, e.g., along a central (e.g., vertical) axis of the component or any other suitable axis. Each slice may define a thin cross section of the component for a predetermined height of the slice. The plurality of successive cross-sectional slices together form the 3D component. The component is then “built-up” slice-by-slice, or layer-by-layer, until finished.

In this manner, the components described herein may be fabricated using the additive process, or more specifically each layer is successively formed, e.g., by fusing or polymerizing a plastic using laser energy or heat or by sintering or melting metal powder. For example, a particular type of additive manufacturing process may use an energy beam, for example, an electron beam or electromagnetic radiation such as a laser beam, to sinter or melt a powder material. Any suitable laser and laser parameters may be used, including considerations with respect to power, laser beam spot size, and scanning velocity. The build material may be formed by any suitable powder or material.

The condenser 44 may be disposed above the one or more perforated baffles 46, 48, 50, 52 of the example immersion cooling assembly 12 in the vertical direction (i.e., in the +/−Y direction). The condenser 44 may be disposed above the one or more electronic devices 16, 18 disposed in the tank 20 of the example immersion cooling assembly 12 in the vertical direction (i.e., in the +/−Y direction). For example, and without limitation, the condenser 44 may be disposed within the tank 20 above the top surface 32 of the liquid coolant 14 in the tank 20 (e.g., in the volume 30) and along the vertical direction (i.e., in the +/−Y direction).

With reference to FIG. 2, one or more perforated baffles 46, 48, e.g., a first perforated baffle 46 and a second perforated baffle 48, may be disposed in the tank 20 between the first electronic device 16 and the second electronic device 18 along the lateral direction (i.e., in the +/−X direction). The first perforated baffle 46 and/or the second perforated baffle 48 may control lateral fluid movement within the tank 20. For example, the first perforated baffle 46 and/or the second perforated baffle 48 may permit fluid flow laterally through the openings 54 of the first perforated baffle 46 and the second perforated baffle 48.

The first perforated baffle 46 and/or the second perforated baffle 48 may be elongated along the vertical direction (i.e., in the +/−Y direction). That is, a height of the first perforated baffle 46 and/or the second perforated baffle 48 along the vertical direction (i.e., in the +/−Y direction) may be longer that a width of the first perforated baffle 46 and/or the second perforated baffle 48 along the lateral direction (i.e., in the +/−X direction). The first perforated baffle 46 and/or the second perforated baffle 48 may extend along the direction that is perpendicular to both the lateral direction (i.e., in the +/−X direction) and the vertical direction (i.e., in the +/−Y direction) from one from one sidewall 24 (not shown) to the other sidewall 24 (not shown) of the pair of sidewalls 24 (not shown) that are spaced from each other along the direction that is perpendicular to both the lateral direction (i.e., in the +/−X direction) and the vertical direction (i.e., in the +/−Y direction). The first perforated baffle 46 and/or the second perforated baffle 48 may generally be generally planar and normal relative to the lateral direction (i.e., in the +/−X direction).

Although two perforated baffles 46, 48 are shown between the first electronic device 16 and the second electronic device 18, it is to be understood that fewer, i.e., zero or one, or greater, i.e., more than two, perforated baffles could be disposed between the first electronic device 16 and the second electronic device 18.

The one or more perforated baffles 46, 48 disposed between the first electronic device 16 and the second electronic device 18 may be fully submerged in the liquid coolant 14 in the tank 20. That is, the top surface 32 of the liquid coolant 14 in the tank 20 may be above top-most distal ends of the one or more perforated baffles 46, 48 disposed between the first electronic device 16 and the second electronic device 18 along the vertical direction (i.e., in the +/−Y direction). The one or more perforated baffles 46, 48 disposed between the first electronic device 16 and the second electronic device 18 may be partially submerged in the liquid coolant 14 in the tank 20 (not shown). That is, the one or more perforated baffles 46, 48 disposed between the first electronic device 16 and the second electronic device 18 may extend from within the liquid coolant 14 in the tank 20 to above the top surface 32 of the liquid coolant 14 in the tank 20 along the vertical direction (i.e., in the +/−Y direction).

The first perforated baffle 46 may be spaced from the second perforated baffle 48 along the lateral direction (i.e., in the +/−X direction) and define a flow channel 64 between the first perforated baffle 46 and the second perforated baffle 48. The flow channel 64 may be elongated along the vertical direction (i.e., in the +/−Y direction). The flow channel 64 may be free of having other components therein. For example, and without limitation, the flow channel 64 maybe free of having any electronic devices disposed therein. The condenser 44 may be disposed above the flow channel 64 along the vertical direction (i.e., in the +/−Y direction). The condenser 44 may be directly above the flow channel 64. That is, the condenser 44 and the flow channel 64 may overlap along the lateral direction (i.e., in the +/−X direction).

The one or more perforated baffles 46, 48 disposed between the first electronic device 16 and the second electronic device 18, e.g., the first perforated baffle 46 and the second perforated baffle 48, may break up coolant gas-phase bubbles 42 formed in the liquid coolant 14. That is, the first perforated baffle 46 and the second perforated baffle 48 may disperse coolant gas-phase bubbles 42 formed in the liquid coolant 14 within the liquid coolant 14. For example, and without limitation, the openings 54 of the first perforated baffle 46 and the second perforated baffle 48 may be smaller than an average size of bubbles 42 formed by the electronic devices 16, 18 during operation of the first electronic device 16 and the second electronic device 18. The average size of the bubbles 42 may be predetermined, e.g., by measuring the size of bubbles 42 using a photographic technique that includes capturing an image of the bubbles 42 with a camera, then analyzing the image to calculate the bubble diameters based on pixel measurements. The bubbles 42 formed by the electronic devices 16, 18 during operation may flow the through openings 54 of the first perforated baffle 46 or the second perforated baffle 48 into the flow channel 64, e.g., due to lateral forces generated during motion of the vehicle 10. While flowing through the first perforated baffle 46 or the second perforated baffle 48 the bubbles 42 formed by the electronic devices 16, 18 during operation may break into smaller bubbles 42 in the flow channel 64. Within the flow channel 64, the bubbles 42 rise upward in the liquid toward the condenser 44.

With reference to FIG. 3, in some embodiments, one or more perforated baffles 50, 52, e.g., a third perforated baffle 50 and a fourth perforated baffle 52, may be disposed in the tank 20 directly above the one or more electronic devices 16, 18 along the vertical direction (i.e., in the +/−Y direction). That is, the third perforated baffle 50 and/or the fourth perforated baffle 52 may overlap the first electronic device 16 and/or the second electronic device 18 along the lateral direction (i.e., in the +/−X direction) and along the direction that is perpendicular to both the lateral direction (i.e., in the +/−X direction) and the vertical direction (i.e., in the +/−Y direction).

The third perforated baffle 50 and the fourth perforated baffle 52 may control vertical fluid movement within the tank 20. For example, the third perforated baffle 50 and the fourth perforated baffle 52 may permit fluid flow through the openings 56, 58 of the third perforated baffle 50 and the fourth perforated baffle 52 from one side of the respective perforated baffle 50, 52 to an opposite side of such perforated baffle 50, 52.

The third perforated baffle 50 and the fourth perforated baffle 52 may be below the condenser 44. That is, the third perforated baffle 50 and the fourth perforated baffle 52 may be disposed between the one or more electronic devices 16, 18 and the condenser 44 within the tank 20 and along the vertical direction (i.e., in the +/−Y direction). The third perforated baffle 50 and the fourth perforated baffle 52 may be directly below the condenser 44.

The fourth perforated baffle 52 may be disposed above the third perforated baffle 50 along the vertical direction (i.e., in the +/−Y direction). For example, and without limitation, the fourth perforated baffle 52 may be disposed between the condenser 44 and the third perforated baffle 50 along the vertical direction (i.e., in the +/−Y direction).

The third perforated baffle 50 and/or the fourth perforated baffle 52 may extend along the lateral direction (i.e., in the +/−X direction) from one from one sidewall 24 overtop the electronic devices 16, 18 to the other sidewall 24 of the pair of sidewalls 24 that are spaced from each other along the lateral direction (i.e., in the +/−X direction). The third perforated baffle 50 and/or the fourth perforated baffle 52 may extend along the direction that is perpendicular to both the lateral direction (i.e., in the +/−X direction) and the vertical direction (i.e., in the +/−Y direction) from one from one sidewall 24 (not shown) 24 overtop the electronic devices 16, 18 to the other sidewall 24 (not shown) of the pair of sidewalls 24 (not shown) that are spaced from each other along the direction that is perpendicular to both the lateral direction (i.e., in the +/−X direction) and the vertical direction (i.e., in the +/−Y direction). The third perforated baffle 50 and/or the fourth perforated baffle 52 may generally be generally planar and normal relative to the vertical direction (i.e., in the +/−Y direction).

The third perforated baffle 50 and/or the fourth perforated baffle 52 may be elongated along the lateral direction (i.e., in the +/−X direction). That is, a width of the third perforated baffle 50 and/or the fourth perforated baffle 52 along the lateral direction (i.e., in the +/−X direction) may be longer that height of the third perforated baffle 50 and/or the fourth perforated baffle 52 along the vertical direction (i.e., in the +/−Y direction). Although two perforated baffles 50, 52 are shown disposed above the first electronic device 16 and the second electronic device 18, it is to be understood that fewer, i.e., zero or one, or greater, i.e., more than two, perforated baffles could be disposed above the first electronic device 16 and the second electronic device 18.

The one or more perforated baffles 50, 52 disposed above the one or more electronic devices 16, 18 may be fully submerged in the liquid coolant 14 in the tank 20. That is, the top surface 32 of the liquid coolant 14 in the tank 20 may be above top-most distal ends of the one or more perforated baffles 50, 52 disposed above the one or more electronic devices 16, 18 along the vertical direction (i.e., in the +/−Y direction). For example, and without limitation, both the third perforated baffle 50 and the fourth perforated baffle 52 may be fully submerged in the liquid coolant 14. Alternately, the fourth perforated baffle 52 may disposed above the liquid coolant 14 or partially submerged with the third perforated baffle 50 fully submerged in the liquid coolant 14 (not shown), or the fourth perforated baffle 52 may be disposed above the top surface 32 the liquid coolant 14 with the third perforated baffle 50 partially submerged in the liquid coolant 14 (also not shown).

The one or more one perforated baffles 50, 52 disposed in the tank 20 above the one or more electronic devices 16, 18, e.g., the third perforated baffle 50 and the fourth perforated baffle 52, may break up coolant gas-phase bubbles 42 formed in the liquid coolant 14. That is, the third perforated baffle 50 and the fourth perforated baffle 52 may disperse coolant gas-phase bubbles 42 formed in the liquid coolant 14 bubble into smaller bubbles 42 within the liquid coolant 14. For example, and without limitation, the openings 56, 58 of the third perforated plate and the fourth perforated plate may be smaller than the average size of bubbles 42 formed by the electronic devices 16, 18 during operation.

When two or more one perforated baffles 50, 52 are disposed in the tank 20 above the one or more electronic devices 16, 18, e.g., the third perforated baffle 50 and the fourth perforated baffle 52, such perforated baffles 50, 52 may progressively break up coolant gas-phase bubbles 42 formed in the liquid coolant 14, e.g., first into bubbles 42 that are smaller than the bubbles 42 as initially formed in the liquid coolant 14 by the one or more electronic devices 16, 18, and then into even smaller bubbles 42. For example, and without limitation, openings 56 of the third perforated baffle 50 may smaller, e.g., in width, diameter, and/or cross-sectional area, than openings 58 of the fourth perforated baffle 52. The size of the openings 56, 58 the third perforated baffle 50 and/or the fourth perforated baffle 52 may be measured, for example, along the lateral direction (i.e., in the +/−X direction). Additionally or alternately, the openings 56 of the third perforated baffle 50 may be offset from the openings 58 of the fourth perforated baffle 52 along the lateral direction (i.e., in the +/−X direction). That is, the openings 56 of the third perforated baffle 50 and the openings 58 of the fourth perforated baffle 52 may be positioned such that the openings 56 of the third perforated baffle 50 and do not completely overlap the openings 58 of the fourth perforated baffle 52 along the lateral direction (i.e., in the +/−X direction). The openings 56 of the third perforated baffle 50 and the openings 58 of the fourth perforated baffle 52 may be positioned such that the openings 56 of the third perforated baffle 50 are free of having any overlap with the openings 54, 56, 58 of the fourth perforated baffle 52 along the lateral direction (i.e., in the +/−X direction).

Bubbles 42 formed by the electronic devices 16, 18 during operation may flow upward to the third perforated baffle 50 and through the openings 56 of the third perforated baffle 50. Flowing through the openings 56 of the third perforated baffle 50 may reduce size of the bubbles 42. From the openings 56 of the third perforated baffle 50, the bubbles 42 of flow upward to the fourth perforated baffle 52, e.g., contacting solid portions of the fourth perorated baffle between the openings 58 of the fourth perforated baffle 52. The bubbles 42 may then flow through the openings 58 of the fourth perforated plate, further reducing the size and dispersing the bubbles 42.

The third perforated baffle 50 and/or the fourth perforated baffle 52 shown in FIG. 3 may be used in combination with the first perforated baffle 46 and/or the second perforated baffle 48 of FIG. 2 (not shown). In such combination, the third perforated baffle 50 and/or the fourth perforated baffle 52 may be disposed, along the vertical direction (i.e., in the +/−Y direction), above the one or more perforated baffles 46, 48 that are between the first electronic device 16 and the second electronic device 18.

From the above, it is to be appreciated that defined herein is an immersion cooling assembly in a vehicle or other mobile environment, the immersion cooling assembly controlling the temperature of one or more electronic devices and configured to reduce sloshing of liquid coolant during operation of the vehicle.

The adjectives “first,” “second,” and/or the like, are used throughout this document as identifiers and are not intended to signify importance or order.

It is noted that the term “generally” may be utilized herein to represent the inherent degree of uncertainty that may be attributed to any quantitative comparison, value, measurement, or other representation. The term is also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. An immersion cooling assembly for controlling the temperature of electronic devices in a mobile environment, the immersion cooling assembly comprising:
a tank;
a liquid coolant disposed in the tank;
a first electronic device disposed in the tank and at least partially submerged in the liquid coolant;
a second electronic device disposed in the tank and at least partially submerged in the liquid coolant, the second electronic device spaced from first electronic device along a lateral direction; and
a perforated baffle disposed in the tank between the first electronic device and the second electronic device along the lateral direction and at least partially submerged in the liquid coolant
wherein the perforated baffle is configured to break up coolant gas-phase bubbles formed in the liquid coolant caused from a heat generated by the first electronic device or the second electronic device and/or to reduce sloshing of the liquid coolant.

2. The immersion cooling assembly of claim 1, wherein the perforated baffle is elongated along a vertical axis.

3. The immersion cooling assembly of claim 1, wherein the perforated baffle includes a lattice structure.

4. The immersion cooling assembly of claim 1, further comprising a second perforated baffle disposed in the tank between the first electronic device and the second electronic device along the lateral direction.

5. The immersion cooling assembly of claim 4, wherein the perforated baffle is spaced from the second perforated baffle along the lateral direction and defines a flow channel between the perforated baffle and the second perforated baffle.

6. The immersion cooling assembly of claim 5, further comprising a condenser disposed above the flow channel.

7. The immersion cooling assembly of claim 1, further comprising a second perorated baffle disposed above the first electronic device and the second electronic device.

8. The immersion cooling assembly of claim 7, wherein the second perforated baffle is elongated along the lateral direction.

9. The immersion cooling assembly of claim 8, wherein the second perforated baffle is submerged in the liquid coolant.

10. The immersion cooling assembly of claim 9, further comprising a third perforated baffle disposed above the second perforated baffle.

11. The immersion cooling assembly of claim 10, wherein openings of the third perforated baffle are smaller than openings of the second perforated baffle.

12. The immersion cooling assembly of claim 10, wherein openings of the third perforated baffle are offset from openings of the second perforated baffle.

13. An immersion cooling assembly for controlling the temperature of electronic devices in a mobile environment, the immersion cooling assembly comprising:
a tank;
a liquid coolant disposed in the tank;
an electronic device disposed in the tank and submerged in the liquid coolant; and
a perforated baffle disposed in the tank directly above the electronic device and at least partially submerged in the liquid coolant;
wherein the perforated baffle is configured to break up coolant gas-phase bubbles formed in the liquid coolant caused from a heat generated by the electronic device and/or to reduce sloshing of the liquid coolant.

14. The immersion cooling assembly of claim 13, wherein the perforated baffle includes a lattice structure.

15. The immersion cooling assembly of claim 13, further comprising a condenser disposed above the perforated baffle.

16. The immersion cooling assembly of claim 13, wherein the perforated baffle is elongated along a lateral direction and is fully submerged in the liquid coolant.

17. The immersion cooling assembly of claim 13, wherein the tank includes a first sidewall and a second sidewall opposite the first sidewall, and wherein the perforated baffle extends from the first sidewall overtop the electronic device to the second sidewall.

18. The immersion cooling assembly of claim 13, further comprising a second perforated baffle disposed in the tank directly above the electronic device and above the perforated baffle, the second perforated baffle at least partially submerged in the liquid coolant.

19. The immersion cooling assembly of claim 18, wherein openings of the second perforated baffle are smaller than openings of the perforated baffle.

20. The immersion cooling assembly of claim 18, wherein openings of the second perforated baffle are offset from openings of the perforated baffle.
